(19) United States
(12) Patent Application Publication
(10) Pub. No.: US 2026/0118432 A1
(43) Pub. Date: Apr. 30, 2026

(54) FAULT DETECTION ISOLATION AND POSITIONING METHOD FOR GENERAL BATTERY SYSTEM

(71) Applicant: CSG PGC ENERGY STORAGE RESEARCH INSTITUTE, Guangzhou (CN)

(72) Inventors: Rui XIONG, Beijing (CN); Chenxu WANG, Beijing (CN); Man CHEN, Guangzhou (CN); Hao ZHANG, Guangzhou (CN); Yikai LI, Guangzhou (CN); Siwei YU, Beijing (CN); Zihao LIU, Beijing (CN); Zhuoyi LI, Guangzhou (CN); Peng PENG, Guangzhou (CN); Yumin PENG, Guangzhou (CN); Wanzhou SUN, Guangzhou (CN); Jun SHE, Guangzhou (CN); Xiaoyi WANG, Guangzhou (CN)

(73) Assignee: CSG PGC ENERGY STORAGE RESEARCH INSTITUTE, Guangzhou (CN)

(21) Appl. No.: 18/951,886

(22) Filed: Nov. 19, 2024

(30) Foreign Application Priority Data
Oct. 25, 2024 (CN) 202411501433.5

(51) Int. Cl. G01R 31/367; G01R 31/388

(52) U.S. Cl. CPC G01R 31/367; G01R 31/388

(57) ABSTRACT

The present application provides a fault detection isolation and positioning method for a general battery system, only voltage and current data commonly used currently can be utilized to detect, isolate, and position multiple types of faults, including a voltage sensor fault, a current sensor fault, a loose contact, and an electrical core fault. The modeling and calculation processes are simpler, and there is no need to perform additional disassembly and installation of a sensor onto the battery system, thereby providing a simple, efficient, and reliable multi-fault diagnosis solution for the general battery system represented by the lithium ion battery

### CROSS REFERENCE TO RELATED DISCLOSURE

The present application claims priority to Chinese Patent Application No. 202411501433.5, entitled “Fault Detection Isolation and Positioning Method for General Battery System”, and filed Oct. 25, 2024, the contents of which is expressly incorporated herein by reference in its entirety.

### TECHNICAL FIELD

The present disclosure relates to the field of battery system safety state detection and fault diagnosis technologies, and particularly to multi-fault detection, isolation and positioning technology for a large-scale series-parallel battery system.

### BACKGROUND

At present, for a complex battery system formed by a large quantity of battery cells and branches, an internal fault cannot be completely avoided. In the art, the fault diagnosis technology plays a key role in the reliability management of the battery system, because the causes of various faults and the electrical coupling phenomenon between the battery cells are still not completely understood. Accurate fault diagnosis can not only ensure the safe operation of the battery system, but also effectively reduce the risk of thermal out-of-control fire accidents caused by faults. The fault diagnoses for the general-purpose battery systems are mostly implemented based on the threshold detection. In such a manner, it is difficult to detect and isolate a fault accurately and quickly at a system level by using limited sensing information. Accordingly, the fault is difficult to be quickly and accurately dealt with, which may greatly increase the safety risk of the battery system. In addition, the existing fault diagnosis method is generally designed for a single fault type, but lacks systematic fault modeling and isolation designs, so that the existing fault diagnosis method is prone to false alarms.

### SUMMARY

In view of this, for the technical problem in the art, the present disclosure provides a fault detection isolation and positioning method for a general battery system, including:
at step 1, acquiring structural parameters of a battery system, the structural parameters includes the number of battery cells, and serial-to-parallel forms of the battery cells; and acquiring an open-circuit voltage (OCV) of a battery cell, and model parameters for modeling the battery cell and the system;
at step 2, establishing a battery cell model according to voltage and current characteristics of the battery cell, establishing a residual-based battery system fault diagnosis model according to the established battery cell model and a structure of the battery system, to calculate residuals corresponding to the battery cell, a branch, and the entire battery system respectively, and establishing a mapping relationship between combinations of three-level residuals and different fault types;
at step 3, initializing a fault diagnosis process, wherein the initializing the fault diagnosis process at least includes: setting initial states of the battery cell and the battery system and parameters for a state estimation algorithm of the battery cell, and setting that time t=0, the initial states including an open-circuit voltage (OCV) and a state of charge (SOC);
at step 4, setting that t=t+1, performing a state estimation algorithm to update a state variable of the battery cell, and calculating the OCV, the SOC, and polarization voltage parameters;
at step 5, inputting the OCV, the SOC, and the polarization voltage parameters obtained by the calculation at the step 4 into the residual-based battery system fault diagnosis model established at step 2 to calculate the three-level residuals; comparing each residual to a given threshold value, converting each residual into a logical quantity including only 0 and 1, and defining the logical quantity as a residual mark quantity;
at step 6, determining whether a fault occurs by using a combination of residual mark quantities, determining that no fault occurs when all elements in the residual mark quantities are equal to 0, and returning to the step 4; when there exists an element in the residual mark quantities not equal to 0, performing a step 7;
at step 7, obtaining a fault mapping table between the combinations of different residual mark quantities and the different fault types by converting the mapping relationship obtained in the step 2, obtaining a fault type and a positioning result by querying the table, outputting a fault diagnosis conclusion and returning to the step 4.

Furthermore, the step 1 further includes: acquiring effects of a corrected temperature, aging, and SOC changes on other parameters, to improve a precision of subsequent modeling.

Furthermore, the establishing the battery cell model at the step 2 includes:
selecting an equivalent circuit model capable of at least describing current charge, a polarization state of the battery cell, wherein the polarization state includes the SOC, the OCV, and the polarization voltage;
defining a form of a three-level residual r as follows;

$$r = [ {r}_{1} , {r}_{2} , {r}_{3} ] ,$$

where a cell residual r₁ of a first element is a matrix of p×s, p represents the number of parallel branches, and s represents the number of cells in series on each branch, r₁ is in a one-to-one correspondence with each cell in the battery system; a branch residual r₂ of a second element is a vector with a length of p, and is in a one-to-one correspondence with each branch; a system residual r₃ of a third element is a scalar, and calculation formulas for the elements in the residuals are as follows:

$$\{ \begin{matrix}{r}_{1 , ij} = O C {v}_{ij} - {y}_{{I}_{i}} {R}_{ij} - {U}_{D , ij} ( k ) - {y}_{{U}_{ij}} \\ {r}_{2 , i} = {y}_{U} - {\sum }_{j = 1}^{s} {y}_{{U}_{ij}} - {y}_{{I}_{i}} {R}_{i} \\ {r}_{3} = {y}_{I} - {\sum }_{i = 1}^{p} {y}_{{I}_{i}}\end{matrix} ,$$

where k represents a moment, the subscript i represents a branch, with i=1, 2, 3, . . . , p, the subscript j represents the j-th battery cell on a branch, with j=1, 2, 3, . . . , s; OCV, R, and UD respectively represent an open-circuit voltage, an ohmic internal resistance, and the polarization voltage of the battery cell; and y_{I}, y_{U}, y_{Ii}, and y_{Uij} respectively represent a total current, a total voltage, a branch current, and a cell voltage indicated by sensors.

Furthermore, in the step 4, real-time voltage and current data serve as inputs of the state estimation algorithm, and Δt serves as a sampling interval to perform the state estimation, and the estimation result is corrected by estimation error feedback.

Furthermore, after the three-level residuals are calculated and compared to the given threshold value in the step 6, obtaining a residual mark quantity combination r′ that includes only elements 0 and 1; in the mapping table obtained by converting the mapping relationship between the combinations of the third-level residuals and different fault types in the step 7, searching for a fault characteristic quantity f corresponding to the residual mark quantity combination r′, to implement diagnoses of fault positions corresponding to different fault types.

In the above-mentioned fault detection isolation and positioning method for the general battery system provided in the present disclosure, only voltage and current data commonly used currently can be utilized to detect, isolate, and position multiple types of faults, including a voltage sensor fault, a current sensor fault, a loose contact, and an electrical core fault. The modeling and calculation processes are simpler, and there is no need to perform additional disassembly and installation of a sensor onto the battery system, thereby providing a simple, efficient, and reliable multi-fault diagnosis solution for the general battery system represented by the lithium ion battery.

### BRIEF DESCRIPTION OF THE DRAWINGS

FIG. 1 is a flow chart showing a method according to the present disclosure.

FIG. 2 is a schematic diagram of a diagnostic result when a voltage sensor fault occurs in a specific branch and cell according to the present disclosure.

### DETAILED DESCRIPTION

The technical solution in the embodiments of the present disclosure will be clearly and completely described below with reference to the accompanying drawings. Obviously, the described embodiments are only some embodiments of the present disclosure, but not all the embodiments. Based on the embodiments of the present disclosure, all other embodiments obtained by those of ordinary skill in the art without creative efforts shall fall within the protection scope of the present disclosure.

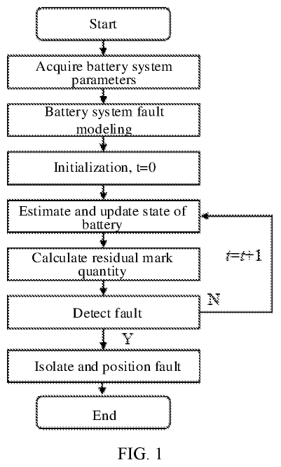

In an embodiment of the present disclosure, a fault detection isolation and positioning method for a general battery system is provided, as shown in FIG. 1, which may specifically include the following steps.

Step 1: structural parameters of a battery system are acquired, the structural parameters include the number of battery cells, and serial-to-parallel forms of the battery cells, and an open-circuit voltage (OCV) of a battery cell, and model parameters for modeling the battery cell and the system are acquired.

Step 2: a battery cell model is established according to voltage and current characteristics of the battery cell, a residual-based battery system fault diagnosis model is established according to the established battery cell model and a structure of the battery system, to calculate residuals corresponding to the battery cell, the branch, and the entire battery system respectively, and a mapping relationship between combinations of three-level residuals and different fault types is established.

Step 3: a fault diagnosis process is initialized, which may include: initial states of the battery cell and the battery system are set, including an open-circuit voltage (OCV) and a state of charge (SOC), and algorithm parameters for estimating the state of the battery cell are set, for example, a process noise covariance matrix and a measurement noise covariance matrix that are related to the Kalman filtering, and it is set that time t=0.

Step 4: it is set that t=t+1, a state estimation algorithm is performed to update a state variable of the battery cell, and the parameters such as OCV, SOC, and a polarization voltage are calculated.

Step 5: the parameters obtained by means of the calculation in step 4 are input into the fault diagnosis model established in the step 2 to calculate the three-level residuals; by comparing each residual to a given threshold value, each residual is converted into a logical quantity including only 0 and 1, and the logical quantity is defined as a residual mark quantity.

Step 6: whether a fault occurs is determined by using a combination of residual mark quantities; when all elements in the residual mark quantities are equal to 0, no fault occurs, and the process is returned to the step 4; when there exists an element in the residual mark quantities not equal to 0, step 7 is performed.

Step 7: a fault mapping table between combinations of different residual mark quantities and different fault types is obtained by converting the mapping relationship obtained in the step 2, a fault type and a positioning result are obtained by querying the table, a fault diagnosis conclusion is output, and the process is returned to the step 4.

In an embodiment of the present disclosure, a fault diagnosis is performed on a lithium-ion battery system with two cells in series and two cells in parallel by using the above-mentioned method. Two branches of the battery system with two cells in series and two cells in parallel are respectively denoted as s and p. Accordingly, the four battery cells are respectively denoted as s1, s2, p1, and p2.

In the step 1, the effect of the corrected temperature, aging, and SOC changes on other parameters is further obtained, in order to improve the precision of subsequent modeling.

A second-order RC equivalent circuit model is established for the battery cells.

A specific form of the three-level residual r is defined as follows:

$$r = [ {r}_{1} , {r}_{2} , {r}_{3} ] ;$$

where the cell residual r₁ of the first element is a matrix of p×s, p represents the number of parallel branches, and s represents the number of cells in series on each branch. Accordingly, r₁ is in a one-to-one correspondence with each cell in the battery system. The branch residual r₂ of the second element is a vector with a length of p, and is in a one-to-one correspondence with each branch. The system residual r₃ of the third element is a scalar. Calculation formulas for the elements in the residual are as follows:

$$\{ \begin{matrix}{r}_{1 , ij} = O C {v}_{ij} - {y}_{{I}_{i}} {R}_{ij} - {U}_{D , ij} ( k ) - {y}_{{U}_{ij}} \\ {r}_{2 , i} = {y}_{U} - {\sum }_{j = 1}^{s} {y}_{{U}_{ij}} - {y}_{{I}_{i}} {R}_{i} \\ {r}_{3} = {y}_{I} - {\sum }_{i = 1}^{p} {y}_{{I}_{i}}\end{matrix} ;$$

where k represents a moment; the subscript i represents a branch, with i=1, 2, 3, . . . , p; the subscript j represents the j-th battery cell on a branch, with j=1, 2, 3, . . . , s; OCV, R, and UD respectively represent an open-circuit voltage, an ohmic internal resistance, and a polarization voltage of a battery cell; and y_{I}, y_{U}, y_{Ii}, and y_{Uij} respectively represent a total current, a total voltage, a branch current, and a cell voltage indicated by sensors.

In the step 4, the real-time voltage and current data serve as inputs of the state estimation algorithm, the Kalman filtering algorithm is selected and Δt is used as a sampling interval to perform the state estimation, and the estimation result is corrected by estimation error feedback.

In the step 6, after the three-level residuals are calculated and compared to the given threshold value, a residual mark quantity combination r′ that includes only elements 0 and 1 is obtained. In the step 7: in the mapping table obtained by converting the mapping relationship between the combinations of the third-level residuals and different fault types, a fault characteristic quantity f of the same combination is searched for, that is, the diagnoses of the fault positions corresponding to different fault types are implemented. The mapping table shown in Table 1 below is specifically adopted in the embodiment.

TABLE 1
Mapping table of fault type, position and residual mark quantity

| Serial | | Fault | | | |
|---|---|---|---|---|---|
| number | Fault type | position | f₁ | f₂ | f₃ |
| 1 | No fault | — | $[ \begin{matrix}0 & 0 \\ 0 & 0\end{matrix} ]$ | $[ \begin{matrix}0 \\ 0\end{matrix} ]$ | 0 |
| 2 | Battery voltage sensor fault | s1 | $[ \begin{matrix}1 & 0 \\ 0 & 0\end{matrix} ]$ | $[ \begin{matrix}1 \\ 0\end{matrix} ]$ | 0 |
| 3 | | s2 | $[ \begin{matrix}0 & 1 \\ 0 & 0\end{matrix} ]$ | $[ \begin{matrix}1 \\ 0\end{matrix} ]$ | 0 |
| 4 | | p1 | $[ \begin{matrix}0 & 0 \\ 1 & 0\end{matrix} ]$ | $[ \begin{matrix}0 \\ 1\end{matrix} ]$ | 0 |
| 5 | | p2 | $[ \begin{matrix}0 & 0 \\ 0 & 1\end{matrix} ]$ | $[ \begin{matrix}0 \\ 1\end{matrix} ]$ | 0 |
| 6 | Branch current sensor fault | s | $[ \begin{matrix}1 & 1 \\ 0 & 0\end{matrix} ]$ | $[ \begin{matrix}1 \\ 0\end{matrix} ]$ | 1 |
| 7 | | p | $[ \begin{matrix}0 & 0 \\ 1 & 1\end{matrix} ]$ | $[ \begin{matrix}0 \\ 1\end{matrix} ]$ | 1 |
| 8 | Loose contact | s | $[ \begin{matrix}0 & 0 \\ 0 & 0\end{matrix} ]$ | $[ \begin{matrix}1 \\ 0\end{matrix} ]$ | 0 |
| 9 | | p | $[ \begin{matrix}0 & 0 \\ 0 & 0\end{matrix} ]$ | $[ \begin{matrix}0 \\ 1\end{matrix} ]$ | 0 |
| 10 | Total voltage sensor fault | — | $[ \begin{matrix}0 & 0 \\ 0 & 0\end{matrix} ]$ | $[ \begin{matrix}1 \\ 1\end{matrix} ]$ | 0 |
| 11 | Total current sensor fault | — | $[ \begin{matrix}0 & 0 \\ 0 & 0\end{matrix} ]$ | $[ \begin{matrix}0 \\ 0\end{matrix} ]$ | 1 |
| 12 | Electrical core fault | s1 | $[ \begin{matrix}1 & 0 \\ 0 & 0\end{matrix} ]$ | $[ \begin{matrix}0 \\ 0\end{matrix} ]$ | 0 |
| 13 | | s2 | $[ \begin{matrix}0 & 1 \\ 0 & 0\end{matrix} ]$ | $[ \begin{matrix}0 \\ 0\end{matrix} ]$ | 0 |
| 14 | | p1 | $[ \begin{matrix}0 & 0 \\ 1 & 0\end{matrix} ]$ | $[ \begin{matrix}0 \\ 0\end{matrix} ]$ | 0 |
| 15 | | p2 | $[ \begin{matrix}0 & 0 \\ 0 & 1\end{matrix} ]$ | $[ \begin{matrix}0 \\ 0\end{matrix} ]$ | 0 |

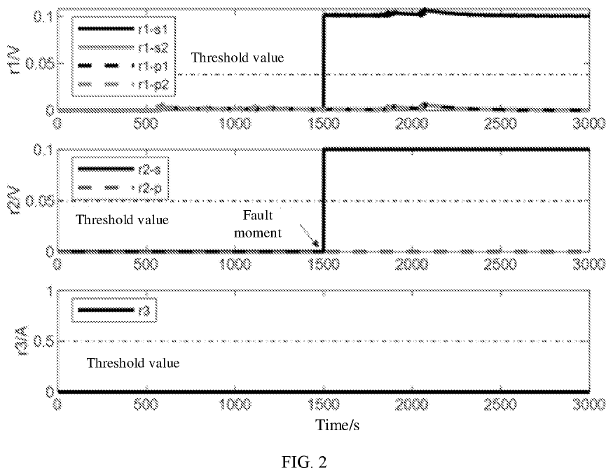

By querying the table, it is successfully found that a voltage sensor fault exists in the first cell of the branch s in the embodiment, as shown in FIG. 2.

It should be appreciated that a sequence number of each step in the embodiment of the present disclosure does not mean a sequence of execution. An execution sequence of each process should be determined according to a function and internal logic of the step, and should not constitute any limitation on an implementation process in the embodiment of the present disclosure.

Although embodiments of the present disclosure are shown and described, those skilled in the art can make several variations, modifications, replacements and deformations without departing from the principle of the present disclosure. The scope of the present disclosure is subject to the appended claims and the equivalents thereof.

What is claimed is:

1. A fault detection isolation and positioning method for a general battery system, the method comprising:
at step 1, acquiring structural parameters of the battery system, the structural parameters including the number of battery cells, and serial-to-parallel forms of the battery cells, and acquiring an open-circuit voltage (OCV) of a battery cell, and model parameters for modeling the battery cell and the system;
at step 2, establishing a battery cell model according to voltage and current characteristics of the battery cell, establishing a residual-based battery system fault diagnosis model according to the established battery cell model and a structure of the battery system, to calculate residuals corresponding to the battery cell, a branch, and the entire battery system respectively, and establishing a mapping relationship between combinations of three-level residuals and different fault types;
at step 3, initializing a fault diagnosis process, wherein the initializing the fault diagnosis process at least includes: setting initial states of the battery cell and the battery system and parameters for a state estimation algorithm of the battery cell, and setting that time t=0, the initial states including an open-circuit voltage (OCV) and a state of charge (SOC);
at step 4, setting that t=t+1, performing the state estimation algorithm to update a state variable of the battery cell, and calculating the OCV, the SOC, and polarization voltage parameters;
at step 5, inputting the OCV, the SOC, and the polarization voltage parameters obtained by the calculation at the step 4 into the residual-based battery system fault diagnosis model established at step 2 to calculate the three-level residuals; comparing each residual to a given threshold value, converting each residual into a logical quantity including only 0 and 1, and defining the logical quantity as a residual mark quantity;
at step 6, determining whether a fault occurs by using a combination of residual mark quantities, determining that no fault occurs when all elements in the residual mark quantities are equal to 0, and returning to the step 4; when there exists an element in the residual mark quantities not equal to 0, performing a step 7;
at step 7, obtaining a fault mapping table between the combinations of different residual mark quantities and the different fault types by converting the mapping relationship obtained in the step 2, obtaining a fault type and a positioning result by querying the table, outputting a fault diagnosis conclusion and returning to the step 4.

2. The method according to claim 1, wherein step 1 further includes acquiring effects of a corrected temperature, aging, and SOC changes on other parameters, to improve a precision of subsequent modeling.

3. The method according to claim 1, wherein establishing the battery cell model at the step 2 includes:
selecting an equivalent circuit model capable of at least describing current charge, a polarization state of the battery cell, wherein the polarization state includes the SOC, the OCV, and the polarization voltage;
defining a form of a three-level residual r as follows:
$$r = [ {r}_{1} , {r}_{2} , {r}_{3} ] ,$$
wherein a cell residual r₁ of a first element is a matrix of p×s, p represents the number of parallel branches, and s represents the number of cells in series on each branch, r₁ is in a one-to-one correspondence with each cell in the battery system; a branch residual r₂ of a second element is a vector with a length of p, and is in a one-to-one correspondence with each branch; a system residual r₃ of a third element is a scalar, and calculation formulas for the elements in the residuals are as follows:
$$\{ \begin{matrix}{r}_{1 , ij} = O C {v}_{ij} - {y}_{{I}_{i}} {R}_{ij} - {U}_{D , ij} ( k ) - {y}_{{U}_{ij}} \\ {r}_{2 , i} = {y}_{U} - {\sum }_{j = 1}^{s} {y}_{{U}_{ij}} - {y}_{{I}_{i}} {R}_{i} \\ {r}_{3} = {y}_{I} - {\sum }_{i = 1}^{p} {y}_{{I}_{i}}\end{matrix} ,$$
wherein k represents a moment, the subscript i represents a branch, with i=1, 2, 3, . . . , p, the subscript j represents the j-th battery cell on a branch, with j=1, 2, 3, . . . , s; OCV, R, and UD respectively represent an open-circuit voltage, an ohmic internal resistance, and the polarization voltage of the battery cell; and y_{I}, y_{U}, y_{Ii}, and y_{Uij} respectively represent a total current, a total voltage, a branch current, and a cell voltage indicated by sensors.

4. The method according to claim 1, wherein at step 4, real-time voltage and current data serve as inputs of the state estimation algorithm, and Δt serves as a sampling interval to perform the state estimation, and the estimation result is corrected by a estimation error feedback.

5. The method according to claim 1, wherein after the three-level residuals are calculated and compared to the given threshold value in the step 6, obtaining a residual mark quantity combination r′ that includes only elements 0 and 1; in the mapping table obtained by converting the mapping relationship between the combinations of the third-level residuals and different fault types in the step 7, searching for a fault characteristic quantity f corresponding to the residual mark quantity combination r′, to implement diagnoses of fault positions corresponding to different fault types.
